(19) United States
(12) Patent Application Publication
(10) Pub. No.: US 2026/0086115 A1
(43) Pub. Date: Mar. 26, 2026

(54) MICROSTRUCTURE INSPECTION DEVICE AND SYSTEM AND USE OF THE SAME

(71) Applicant: Silex Microsystems AB, Järfälla (SE)

(72) Inventor: Andreas FISCHER, Järfälla (SE)

(21) Appl. No.: 19/109,254

(22) PCT Filed: Sep. 7, 2023
(86) PCT No.: PCT/EP2023/074588

§ 371 Date: Mar. 6, 2025

(30) Foreign Application Priority Data
Sep. 8, 2022 (SE) 2251043-2

(51) Int. Cl. G01R 1/067

(52) U.S. Cl. CPC G01R 1/06716; G01R 1/06744

(57) ABSTRACT

A microstructure inspection device and system for inspecting an electrical characteristic of at least one micro electromechanical system (MEMS) structure formed in or on a substrate including a probe tip having an electrically conductive and elastically deformable probe tip surface configured to deform elastically when subjected to a force greater than a predetermined deformation threshold value, and a pusher for pushing the probe tip in a first direction against the substrate with an abutment force that is greater than the predetermined deformation threshold value, thereby causing the probe tip surface to deform elastically. The pusher is configured to push the probe tip in the first direction and/or a substrate pusher is configured to push the substrate against the probe tip with an abutment force that is greater than the predetermined deformation threshold value, thereby causing the probe tip surface to deform elastically.

### TECHNICAL FIELD

The present invention relates to a microstructure inspection device for inspecting an electrical characteristic of at least one micro electromechanical system, MEMS, structure formed in and/or on a substrate. The present invention also relates to a microstructure inspection system for inspecting an electrical characteristic of at least one micro electromechanical system, MEMS, structure formed in and/or on a substrate. The present invention further relates to the use of such a microstructure inspection device or microstructure inspection system.

### BACKGROUND

Manufacturing of micro electromechanical systems (MEMS) or integrated circuits can be divided into two steps, the first being wafer fabrication and the second being assembly, which is the process of packaging the die. These two steps, or phases, are also commonly referred to as “Front-End” and “Back-End”. Both phases typically include two or more electrical test steps at wafer-level, die-level and/or component-level, depending on the application. Electrical probing usually takes place between wafer fabrication and assembly and helps to identify bad components and only sending known-good components to back-end processing. In other words, electrical probing verifies the functionality of the device, by performing dedicated electrical tests with the help of a probe station. This setup is comprised of electrical test equipment (e.g. DMM, SMU, VNA, etc.) that is connected to a probe fixation device that is arranged to act as an interface between an electronic test equipment and the device under test (DUT), e.g. being a MEMS structure. The prober typically comprises a probe card that has contact elements, such as e.g. probe needles, that are brought into contact with the DUT. These contact elements are typically made of tungsten, alloys of tungsten or palladium-based alloys. The contact elements are pushed against metal contact pads on the DUT. Similar tests can be performed both at wafer- and die-level.

A manufactured micro electromechanical system (MEMS) integrated circuit must be tested by electrical probing before it is assembled.

A common issue with this known solution is that the contact elements of the probes slightly deform the metal pad surface of the DUT and leave an imprint (if pushed too hard towards the surface) and/or scratches the surface (if a contact element of a probe and/or the metal pad surface of a DUT move in relation to each other during testing).

Another issue is that MEMS components, which are typically comprised of delicate 3D microstructures such as suspended beams, membranes and/or sensitive functional surfaces, cannot be contacted by regular probes as described above without risking damaging features that are essential to the functionality of the device.

Attempts have been made to solve these problems, for example in the related art patent document US2009128171 A1, which discloses a microstructure probe card, and microstructure inspecting device, method, and computer program for electrically inspecting a microstructure with a movable portion without damaging a probe or an inspection electrode. The solution according to US2009128171A1 comprises using two probes for one inspection electrode to cause the inspection electrode provided on the microstructure and a probe provided on the probe card to conduct each other by employing fritting phenomenon.

However, there is still a need for alternative solutions of how to inspect an electrical characteristic of at least one micro electromechanical system, MEMS, structure formed in or on a substrate without risking damaging parts of the delicate MEMS structure and further without leaving an imprint on or scratch the surface of the MEMS structure (also referred to as device under testing, DUT).

### SUMMARY

The object of the invention is to provide a solution for inspecting an electrical characteristic of at least one micro electromechanical system (MEMS) structure formed in or on a substrate, capable of correctly inspecting whether the MEMS structure has a specified electrical performance, prior to assembly, that eliminates or at least to minimizes the problems discussed above. This is achieved by an inspection device and system for inspecting an electrical characteristic of at least one MEMS structure formed in or on a substrate, and further by a method of using the device or system for inspecting an electrical characteristic of at least one MEMS structure formed in or on a substrate, according to the appended independent claims.

In a first aspect of the invention, there is provided a microstructure inspection device for inspecting an electrical characteristic of at least one MEMS structure formed in or on a substrate. The microstructure inspection device comprises a probe tip unit having an electrically conductive and elastically deformable probe tip surface that is configured to deform elastically when subjected to a force greater than a predetermined deformation threshold value. The microstructure inspection device further comprises a push unit for pushing the probe tip unit in a first direction towards a substrate. The push unit is configured to push the probe tip unit in the first direction, i.e. towards the substrate and thus towards or against the MEMS structure formed in or on the substrate, with an abutment force that is greater than the predetermined deformation threshold value.

Suitably, the electrically conductive and elastically deformable probe tip surface will thereby be pushed by the push unit with a force that will cause it to deform elastically when abutted against the surface of the at least one MEMS structure formed in or on the substrate. Thereby, the inspection device can be put into electrical contact with the MEMS structure, or MEMS device under test (DUT), without risking damaging parts of the delicate MEMS structure and further without leaving an imprint on or scratch the surface of the MEMS structure or substrate, if the MEMS structure is formed within the substrate.

The surface area of the electrically conductive and elastically deformable probe tip surface may be in the interval of at least 0.01 mm² and at most 1 cm². In many applications a probe tip surface area may be in the interval 1 mm² to 1 cm². Both these intervals provide suitable outer boundaries for probes used in the application of inspecting MEMS structures, but slightly smaller or larger areas may also be contemplated depending on circumstances. Of course, manufacturing tolerances are always included in any probe tip surface area example given herein. In some embodiments, the surface area of the electrically conductive and elastically deformable probe tip surface may be in the interval of at least 20 mm² and at most 30 mm². In some specific embodiments, the surface area of the electrically conductive and elastically deformable probe tip surface is 25 mm², or approximately 25 mm². As is readily understood by a person skilled in the art, the suitable probe tip surface area depends on the application, since MEMS and integrated circuit (IC) chips and components thereof can differ greatly in size from one application to another. Also, since the probe tip surface is elastically deformable (soft, conformable), this in many cases, especially for soft or very soft materials as further described herein, eliminates, or at least greatly reduces the need for both high precision alignment of the probe tip surface to the MEMS structure to be tested and therefore also allows for increased differences/tolerances on the probe tip surface area size for each application. For each specific case, the selection of the size of the probe tip surface area may typically be selected to be as large as necessary in order to cover all target features on the DUT, including a selected alignment tolerance, and as small as possible in order to minimize the contact area and thereby avoiding affecting and possibly damaging surrounding features, even if this risk is greatly decreased compared to existing probing solutions.

Suitably, an electrically conductive and elastically deformable probe tip surface made of a material (or a combination of materials) that is configured to deform elastically when subjected to a pressure within the interval of 0.0001 MPa to 3 MPa for the given areas is a material that is significantly softer than any material used in the substrate, or MEMS structure formed in or on the substrate, against which it is to be pressed during inspection. Therefore, the electrically conductive and elastically deformable probe tip surface will advantageously deform elastically when pressed against the substrate, or MEMS structure formed in or on the substrate, during inspection without risking damaging parts of the delicate MEMS structure and further without leaving an imprint on or scratch the surface of the MEMS structure. Using the definitions of the Shore hardness scale, materials that deform elastically when subjected to pressure within the interval of 0.0001 MPa to 3 MPa for the given surface areas are defined as either extra soft, soft, or medium soft materials. In some embodiments, the predetermined deformation threshold value may be set to a force that generates a pressure on the probe tip surface that is equal to or more than 0.0001 MPa and equal to or less than 0.15 MPa.

For any of the alternative surface areas of the electrically conductive and any of the elastically deformable probe tip surface materials mentioned herein, the predetermined deformation threshold value may be set to a force that generates a pressure on the probe tip surface that is equal to or more than 0.0001 MPa and equal to or less than 3 MPa when the microstructure inspection device is pushed against the MEMS structure.

Materials that will deform elastically when exposed to pressures within this interval have a shore Durometer value of 0-50 on the Shore 00 hardness scale and are defined as extra soft materials according to the Shore hardness scale. Materials that are electrically conductive and will deform elastically when exposed to pressures within this interval include jelly like and gel like elastomers. Such jelly like and gel like elastomers are therefore suitable materials to be used in the electrically conductive and elastically deformable probe tip surface in these embodiments. In other embodiments, the predetermined deformation threshold value may be set to a force that generates a pressure on the probe tip surface that is equal to or more than 0.15 MPa and equal to or less than 1.5 MPa. Materials that will deform elastically when exposed to pressures within this interval have a shore Durometer value of 25-40 on the Shore A hardness scale and are defined as soft materials according to the Shore hardness scale. Materials that are electrically conductive and will deform elastically when exposed to pressures within this interval include soft elastomers. Non-limiting examples of such soft elastomers that are suitable choices for a material to be used in the electrically conductive and elastically deformable probe tip surface in these embodiments are electrically conductive elastomers such as e.g. electrically conductive silicone. In yet other embodiments, the predetermined deformation threshold value may be set to a force that generates a pressure on the probe tip surface that is equal to or more than 0.03 MPa and equal to or less than 3 MPa. Materials that will deform elastically when exposed to pressures within this interval have a shore Durometer value of 40-60 on the Shore A hardness scale and are defined as medium soft materials according to the Shore hardness scale. Materials that are electrically conductive and will deform elastically when exposed to pressures within this interval include medium-soft elastomers. Some none-limiting examples of such a medium-soft elastomers that are suitable choices for material to be used in the electrically conductive and elastically deformable probe tip surface in these embodiments are nitriles, neoprene, and ethylene propylene. Of course, any other suitable material or material combination fulfilling the criteria of being electrically conductive and deforming elastically when exposed to pressures within any of the above exemplified intervals may also be applied.

Advantageously, for any material fulfilling these criteria, including the examples given, the aim that the inspection device can be put into electrical contact with the MEMS structure, or MEMS device under test (DUT), without risking damaging parts of the delicate MEMS structure and further without leaving an imprint on or scratch the surface of the MEMS structure or substrate, is achieved.

The push unit may be configured to push the probe tip unit in the first direction with said abutment force in response to a control signal from a probe controller communicatively connected to the microstructure inspection device. Thereby, the application of force, or pressure, may suitably be automatically controlled, making the inspection of the electrical characteristic of at least one MEMS structure according to embodiments of the present invention even more robust and reliable. The probe controller is in these embodiments configured to generate a control signal; the control signal being configured to control the push unit of the microstructure inspection device to push the probe tip unit in the first direction with said abutment force.

The push unit may be a linear actuator configured to push the probe tip unit linearly in the first direction with the abutment force. In these embodiments, the push unit may comprise any type of linear actuator, such as a fine-thread screw, a piston, possibly a hydraulic piston, an electromagnetic actuator and/or a piezoelectric actuator.

In some embodiments, the probe tip unit is further tiltably arranged in relation to the push unit.

Suitably, the probe tip will when pressed against a surface self-level by tilting to correct for any angular mismatch or tilt between the probe tip surface and the surface of the DUT, i.e. the surface of the MEMS structure or the surface of the substrate if the MEMS structure to be inspected is formed therein. In other words, the soft, or elastically deformable, and conductive material of the probe tip surface is levelled to be parallel to the surface of the substrate or MEMS structure, or as close to parallel as possible if the probe tip surface and/or the surface of the substrate or MEMS structure is not planar but comprise topography.

A further advantageous effect of the probe tip unit being tiltably arranged in relation to the push unit is that if the push unit is a linear actuator that rotates, e.g. but not limited to in the case where the push unit is a fine-thread screw, the rotation will stop upon contact between the probe tip surface and the surface of the substrate or MEMS structure, thereby eliminating the application of torsional forces on the substrate or MEMS structure by the probe tip surface.

In a second aspect of the invention, there is provided a microstructure inspection system for inspecting an electrical characteristic of at least one MEMS structure formed in or on a substrate. The microstructure inspection system comprises at least one microstructure inspection device, a probe fixation device arranged to hold the at least one microstructure inspection device, and a substrate having at least one MEMS structure formed thereon or therein. The hardness of the at least one MEMS structure to be inspected is higher than the hardness the electrically conductive and elastically deformable probe tip surface of the probe unit of each of the at least one microstructure inspection device. Each microstructure inspection device may be a microstructure inspection device of the first aspect with a push unit for pushing the probe tip unit in a first direction towards the substrate. Alternatively, or additionally, the microstructure inspection system comprises a substrate push unit for pushing the substrate towards the probe tip unit, wherein the push unit is configured to push the probe tip unit in the first direction, or the substrate push unit is configured to push the substrate towards or against the probe tip unit. In one embodiment, each push unit of the at least one microstructure inspection device is configured to push the probe tip unit in the first direction towards the substrate with said abutment force. In another embodiment, the substrate push unit is configured to push the substrate towards the at least one probe tip unit with said abutment force. In a further embodiment, each push unit of the at least one microstructure inspection device is configured to, independently or simultaneously, push its respective probe tip unit in said first direction towards the substrate with a first force and the substrate push unit is configured to push the substrate towards the at least one probe tip unit with a second force, wherein the combination of the first force and the second force is equal to the abutment force.

Suitably, since the hardness of the at least one MEMS structure to be inspected is higher than the hardness the electrically conductive and elastically deformable probe tip surface of the probe unit of each of the at least one microstructure inspection device, the electrically conductive and elastically deformable probe tip surface will deform elastically when abutted against the surface of the at least one MEMS structure formed in or on the substrate. Thereby, the inspection device can be put into electrical contact with the MEMS structure, or MEMS device under test (DUT), without risking damaging parts of the delicate MEMS structure and further without leaving an imprint on or scratch the surface of the MEMS structure or substrate, if the MEMS structure is formed within the substrate.

The hardness of the electrically conductive and elastically deformable probe tip is preferably below or equal to 60 Durometer on the Shore A hardness scale.

Suitably, an electrically conductive and elastically deformable probe tip surface made of a material (or a combination of materials) that has a hardness under 60 Durometer on the Shore A hardness scale is a material that is significantly softer than any material used in the substrate, or MEMS structure formed in or on the substrate, against which it is to be pressed during inspection. Therefore, the electrically conductive and elastically deformable probe tip surface will advantageously deform elastically when pressed against the substrate, or MEMS structure formed in or on the substrate, during inspection without risking damaging parts of the delicate MEMS structure and further without leaving an imprint on or scratch the surface of the MEMS structure. Using the definitions of the Shore hardness scale, materials that have a hardness under 60 Durometer on the Shore A hardness scale are defined as either extra soft, soft, or medium-soft materials.

In some embodiments, the hardness of the electrically conductive and elastically deformable probe tip is in the interval 40-60 Durometer on the Shore A hardness scale, including the end points. Materials that have a shore Durometer value of 40-60 on the Shore A hardness scale are defined as medium soft materials according to the Shore hardness scale. Materials that are electrically conductive and have a shore durometer value of 40-60 on the Shore A hardness scale include medium-soft elastomers.

In some embodiments, the hardness of the electrically conductive and elastically deformable probe tip is in the interval 25-40 Durometer on the Shore A hardness scale, including the end points. Materials that have a shore Durometer value of 25-40 on the Shore A hardness scale and are defined as soft materials according to the Shore hardness scale. Materials that are electrically conductive and have a shore durometer value of 25-40 on the Shore A hardness scale include soft elastomers.

In some embodiments, the hardness of the electrically conductive and elastically deformable probe tip is below or equal to 50 Durometer on the Shore 00 hardness scale. Materials that have a shore Durometer value below or equal to 50 Durometer on the Shore 00 hardness scale are defined as extra soft materials according to the Shore hardness scale. Materials that are electrically conductive and have a shore durometer value below or equal to 50 Durometer on the Shore 00 hardness scale include jelly like and gel like elastomers.

Of course, any other suitable material or material combination fulfilling the criteria of being electrically conductive and having a hardness under 60 Durometer on the Shore A hardness scale. Advantageously, for any material fulfilling these criteria, including the examples given, the aim that the inspection device can be put into electrical contact with the MEMS structure, or MEMS device under test (DUT), without risking damaging parts of the delicate MEMS structure and further without leaving an imprint on or scratch the surface of the MEMS structure or substrate, is achieved.

The microstructure inspection system may further comprise a probe controller configured to generate a control signal. The control signal may be configured to control each push unit of the at least one microstructure inspection device, independently or simultaneously, to push its respective probe tip unit in the first direction with said abutment force. Alternatively, the control signal may be configured to control the substrate push unit to push the substrate towards the at least one probe tip unit with said abutment force. Alternatively, the control signal may be configured to control each push unit of the at least one microstructure inspection device, independently or simultaneously, to push its respective probe tip unit in said first direction with a first force and control the substrate push unit to push the substrate in the opposite direction, i.e. towards the at least one probe tip unit with a second force, wherein the combined force (the first force plus the second force) applied by the at least one push unit and the substrate push unit is equal to said abutment force. Thereby, the application of force, or pressure, may suitably be automatically controlled, making the inspection of the electrical characteristic of at least one MEMS structure according to embodiments of the present invention even more robust and reliable.

A third aspect of the invention includes the use of a microstructure inspection device or a microstructure inspection system according to any of the embodiments described herein, that is in the summary, detailed description, or the claims, for inspecting an electrical characteristic of at least one micro electromechanical system, MEMS, structure formed in or on a substrate.

Any advantage described in connection with one aspect of the invention, e.g. the microstructure inspection device, is equally applicable to corresponding embodiments of other aspects of the invention, e.g. the microstructure inspection system and the use of the microstructure inspection device or the microstructure inspection system.

Many additional benefits and advantages of the present invention will be readily understood by the skilled person in view of the detailed description below.

### DRAWINGS

The invention will now be described in more detail with reference to the appended drawings, wherein:

FIG. 1 schematically discloses a microstructure inspection device according to an embodiment of the invention;

FIG. 2 schematically discloses a microstructure inspection device according to an embodiment of the invention;

FIG. 3 schematically discloses a microstructure inspection system according to an embodiment of the invention;

FIG. 4 is a flow chart showing a method of using a microstructure inspection device or a microstructure inspection system according to an embodiment of the invention;

FIG. 5a schematically discloses a microstructure inspection device being pushed in a first direction towards a substrate having a MEMS structure formed thereon;

FIG. 5b schematically discloses a microstructure inspection device being pressed against a substrate having a MEMS structure formed thereon;

FIG. 6a schematically discloses a microstructure inspection device being pushed in a first direction towards a substrate having a MEMS structure formed therein;

FIG. 6b schematically discloses a microstructure inspection device being pressed against a substrate having a MEMS structure formed therein;

FIG. 6c schematically discloses a microstructure inspection device being pressed against a substrate having a MEMS structure formed therein;

FIG. 7a schematically discloses a microstructure inspection device or system wherein the probe tip unit is tiltably arranged in relation to the push unit;

FIG. 7b schematically discloses a microstructure inspection device or system wherein the probe tip unit is tiltably arranged in relation to the push unit;

FIG. 8a schematically discloses functional MEMS structures in and/or on a substrate;

FIG. 8b schematically discloses electrically inspecting the functional MEMS structures of FIG. 8a using one or more embodiment of the invention;

FIG. 8c schematically discloses electrically inspecting the functional MEMS structures of FIG. 8a using one or more embodiment of the invention; and

FIG. 9 schematically shows two examples of prior art microstructure inspection devices with a respective hard probe tip surface being pressed against a substrate.

All the figures are schematic, not necessarily to scale, and generally only show parts which are necessary in order to elucidate the respective embodiments, whereas other parts may be omitted or merely suggested. Any reference number appearing in multiple drawings refers to the same object or feature throughout the drawings, unless otherwise indicated.

### DETAILED DESCRIPTION

There is provided a microstructure inspection device, a microstructure inspection system and the use of the same, as described in embodiments herein, to solve the problem of how to inspect an electrical characteristic of at least one micro electromechanical system, MEMS, structure formed in or on a substrate without risking damaging parts of the delicate MEMS structure (also referred to as device under testing, DUT) and further without leaving an imprint on or scratch the surface of the MEMS structure and/or the surface of the substrate in the case the MEMS structure is at least partly formed within the substrate. In all embodiments herein, the MEMS structure is accessible for electrical testing by a probe tip directed towards the surface of the substrate. In other words, the MEMS structure is not completely covered by the substrate.

The invention thereby includes a microstructure inspection device and a system, and the use of the same, that enables electrical contacting at wafer- and die-level for advanced probing schemes on MEMS and semiconductor devices. Due to the design of the microstructure inspection device and especially the softness of the probe tip surface of the microstructure inspection device (the softness may for example be defined in terms of a high elastic deformability, or a relatively higher softness (lower hardness) compared to surface towards which it is pushed or pressed), the probe tip of the microstructure inspection device exposes a device under test (DUT), e.g. a MEMS structure, to minimal mechanical load, leaving no mechanical deformation or imprints of the contact area, or at least significantly reducing the risk, depending on the material chosen for the probe tip surface. A further advantage is that areas smaller than typical probing pads (>80×80 μm²) can be contacted.

As described herein and illustrated in the figures, the probe tip surface is the part of the probe tip that is in direct physical and electrical contact with the DUT during electrical inspection using the inventive microstructure inspection device or system. In other words, when using embodiments of the present invention for electrical inspection, the DUT surface will be put into direct contact with an electrically conductive and elastically deformable component, i.e. the inventive probe tip surface, which enables electrical contact while reducing or even completely eliminating the risk of the contact areas of the DUT being subjected to mechanical deformation, scratches, imprints etc. This is in contrast to using prior art solutions with hard probe tip surfaces, i.e, wherein an electrically conductive surface that is not elastically deformable (i.e. a hard probe tip surface comprising tungsten or the like) is pressed against the DUT contact surface. In some prior solutions, attempts are made to reduce the pressure of such hard probe tip surfaces against the contact surface of the DUT, e.g. by adding a spring element between the push unit and the probe tip. Thereby, the pressure applied can be controlled. However, this solution is inferior the solution according to embodiments herein, because the hard probe tip surface that is in direct electrical contact with the contact surface of the DUT in these prior solutions still cause the problem of deforming or scratching the DUT surface.

Furthermore, in some embodiments described herein it is possible to simultaneously contact a multitude of contact areas, or MEMS structures, at the same time.

Herein, a “MEMS element”, “MEMS component” or “MEMS structure” refers to a functional device that is three-dimensionally formed by using a technique for manufacturing a MEMS. “Mounting” means joining and integrating a separately manufactured substrate and the MEMS structure or forming the MEMS structure directly in and/or on the substrate.

The MEMS structure, which may hereinafter also be referred to as a three dimensional structure or a component, is the device under test (DUT) that is to be tested using the microstructure inspection device according to embodiments herein. The MEMS structure is either formed on a substrate, in a substrate, or partly in and partly on a substrate, in any manner known in the art.

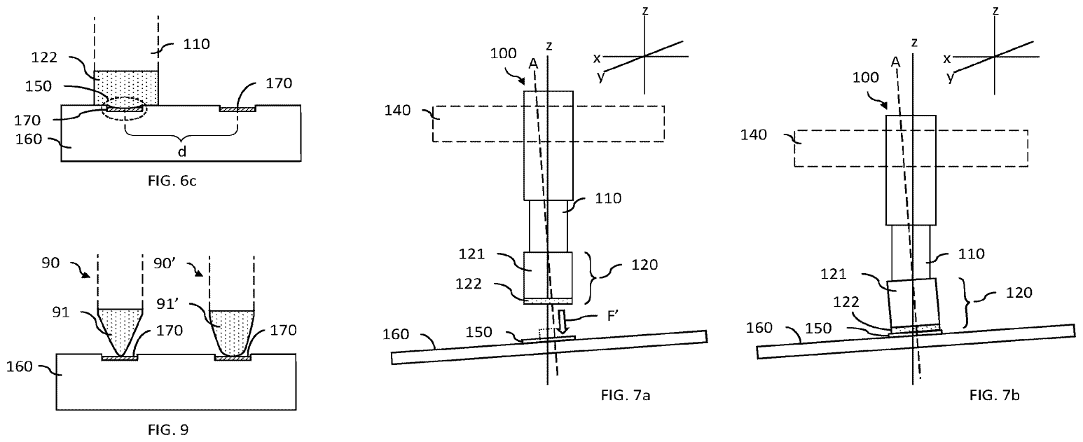

That a MEMS structure is formed in the substrate means that the MEMS structure has not solely been attached to or built on the surface of the substrate but is at least partially located within the substrate. A schematic, non-limiting, example of a MEMS structure formed in the substrate is shown in FIG. 6b, which are further discussed herein. Typically, bulk micro machining is used for forming MEMS structures in, or at least partly in, the substrate and surface micro machining is used for forming MEMS structures on the substrate. Of course, a resulting substrate, chip, die etc. may comprise more than one MEMS structure and the MEMS substrates may be formed in different manners, in and/or on the substrate. In any embodiment, the MEMS structure may be said to form part of the resulting wafer or substrate.

A substrate may also be referred to as a wafer.

Inspection using the microstructure inspection device 100 or microstructure inspection system 200 according to any embodiment herein may be performed on a wafer level, wherein multiple MEMS structures/components, are inspected simultaneously, or on a component level/chip level/die level, inspecting one MEMS structure/component at a time. In either scenario, a probe card or the like may be used for holding more than one microstructure inspection device 100 arranged to contact more than one feature of the MEMS structure for the electrical testing (short-cutting).

It is noted that all sizes, angles, relations etc. given herein are not to be seen as only covering the exact given values but also include minor variations due to manufacturing tolerances. It is also to be noted that features from the various embodiments described herein may freely be combined, unless it is explicitly stated that such a combination would be unsuitable.

With proper adaptations, the inventive inspection device, system, and method may be used not only for testing MEMS structures but may possibly also be applied to test one or more electrically conductive three dimensional structure formed on or in (as part of) a substrate, such as for example a semiconductor or another electronic device or system. However, the advantages of the inventive solution are especially significant when the inventive inspection device, system and/or method is used for microstructures, such as MEMS, since the small size of such structures renders them practically impossible to test/probe/inspect electrically in any other manner except using an inspection method involving very thin and pointed probes that always risk introducing the problem of scratching or otherwise deforming the surface of the structure or device under test (DUT).

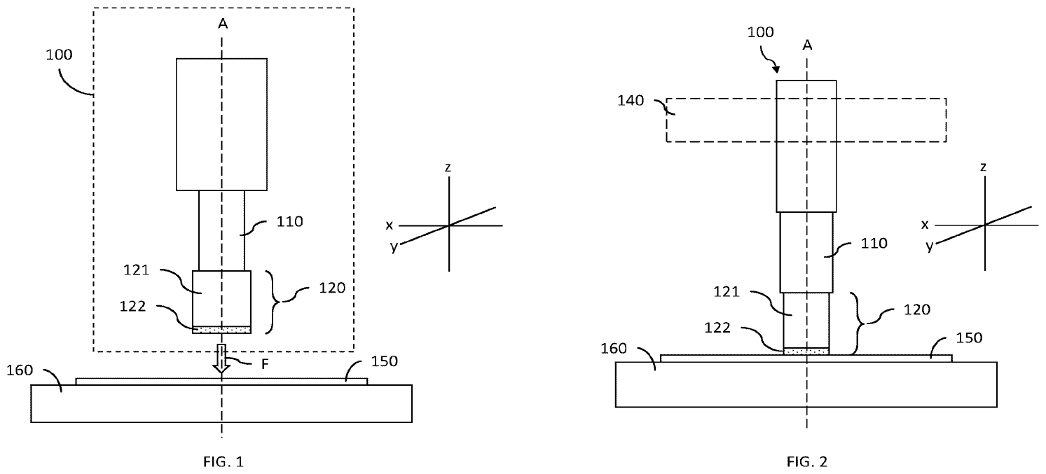

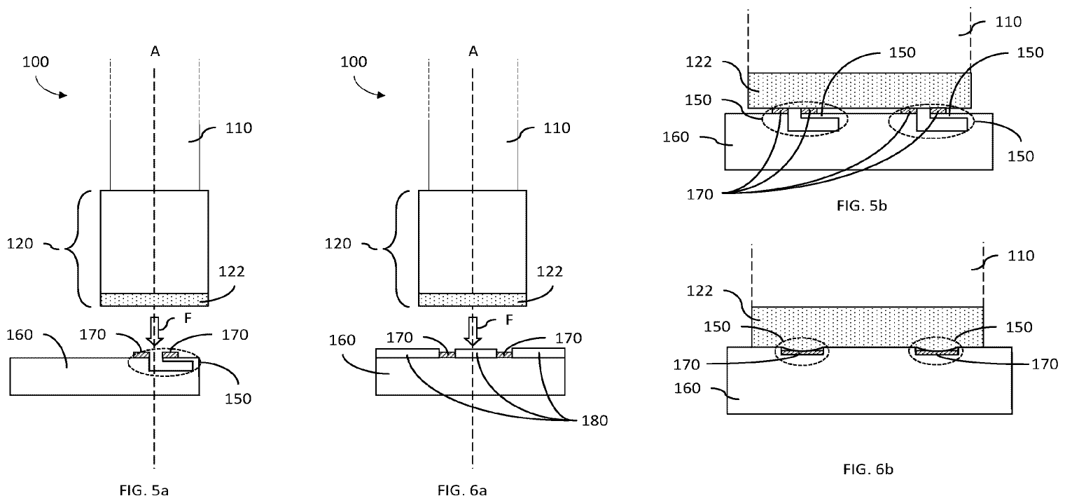

In a first aspect of the invention, a microstructure inspection device 100 for inspecting an electrical characteristic of at least one micro electromechanical system, MEMS, structure 150 formed in or on a substrate 160 will first be described with reference to FIGS. 1 and 2, and further with reference to FIGS. 5a, 5b, 6a, 6b, 7a and 7b.

FIG. 1 shows a microstructure inspection device 100 for inspecting an electrical characteristic of at least one micro electromechanical system, MEMS, structure 150 formed in and/or on a substrate 160. The microstructure inspection device 100 comprises a probe tip unit 120 having an electrically conductive and elastically deformable probe tip surface 122 configured to deform elastically when subjected to a force greater than a predetermined deformation threshold value. The microstructure inspection device 100 further comprises a push unit 110 for pushing the probe tip unit 120 in a first direction towards a substrate 160. The push unit 110 is configured to push the probe tip unit 120 in the first direction with an abutment force, said abutment force being greater than the predetermined deformation threshold value. Suitably, the electrically conductive and elastically deformable probe tip surface 122, being a part of the probe tip unit 120, will thereby be pushed by the push unit with a force that will cause it to deform elastically when abutted against the surface of the at least one MEMS structure formed in or on the substrate. As shown in the figures, the probe tip surface 122 is the surface at the distal end of the probe tip unit 120, facing away from the push unit 110 and, during use, facing towards the substrate 160 and MEMS structure 150 to be inspected. Thereby, the inspection device can be put into electrical contact with the MEMS structure, or MEMS device under test (DUT), without risking damaging parts of the delicate MEMS structure and further without leaving an imprint on or scratch the surface of the MEMS structure or substrate, if the MEMS structure is formed within the substrate. The push unit 110 may be a linear actuator configured to push the probe tip unit 120 linearly in the first direction, i.e. towards or against the substrate 160, with the abutment force. In these embodiments, the push unit 110 may comprise for example a fine-thread screw, a piston, possibly a hydraulic piston, an electromagnetic actuator and/or a piezoelectric actuator, and/or any other suitable actuator. Of course, any other suitable linear actuator configured to push the probe tip unit 120 in the first direction with the abutment force may alternatively be used, or a suitable combination of linear actuators. In embodiments wherein it is important that the placement of the microstructure inspection device 110 is made with a very high degree of accuracy, the linear actuator of the push unit 110 may suitably be a piezoelectric actuator, as this technology enables the high precision required for this purpose.

That the push unit 110 is configured to push the probe tip unit 120 in the first direction, i.e. towards or against the substrate 160, may mean that it is configured to bring the probe tip surface 122 into physical contact with the MEMS structure 150, thereby causing the conductive and elastically deformable probe tip surface 122 to create an ohmic contact between the microstructure inspection device 100 and a MEMS structure 150 on the substrate 160. During electrical inspection using the microstructure inspection device 100 according to any embodiment herein, this may mean bringing the probe tip surface 122 into physical contact with only the MEMS structure 150 if the MEMS structure 150 is formed at least partly on the substrate 160 and a surface part of the MEMS structure that is to be contacted protrudes from the substrate 160. FIG. 5a schematically discloses a microstructure inspection device 100, according to any of the embodiments herein, being pushed in the first direction towards a substrate 160. The substrate 160 in FIG. 5a has a MEMS structure 150 formed thereon, comprising two electrically conductive contact areas or contact surfaces 170. As shown in FIG. 5b, the microstructure inspection device 100, or specifically the probe tip unit 120 of the microstructure device 100, is pushed towards the substrate 160 until the probe tip surface 122 is put into electrical contact with the electrically conductive contact surfaces 170, thereby enabling electrical inspection of the MEMS structure 150. In the example of FIGS. 5a and 5b, the MEMS structure is a fragile suspended structure, whereby inspection using the soft probe tip surface of the presently disclosed microstructure inspection device 100 greatly reduces the risk of damaging the damaging the fragile elements of the suspended structure. Very sensitive structures, e.g. free-standing structures, small cantilevers, free-standing moving MEMS elements, and/or MEMS structures with very sensitive surfaces may require probe tip surface materials having a hardness in the range of 0-50 on the Shore 00 hardness scale.

Alternatively, or additionally, that the push unit 110 is configured to push the probe tip unit 120 in the first direction towards or against the substrate 160 may mean bringing the probe tip surface 122 into physical contact with the substrate 160 if a surface part of the MEMS structure 150 that is to be contacted is flush with the surface of the substrate 160. This is the simplest case, and it is not specifically illustrated in detail in any of the figures.

Alternatively, or additionally, that the push unit 110 is configured to push the probe tip unit 120 in the first direction, i.e. towards or against the substrate 160, may mean bringing the probe tip 122 into physical contact with the substrate 160 and pushing further to bring the probe tip 122 into physical contact with a surface part of the MEMS structure 150 that is to be contacted, if the MEMS structure 150 is at least partly formed within the substrate 160 and a part of the MEMS structure 150 surface that is to be contacted is located under the surface of the substrate 150, as seen from the probe tip unit 120. FIG. 6a discloses a microstructure inspection device 100, according to any of the embodiments herein, being pushed towards a substrate 160 having two MEMS structures 150 formed therein, i.e. formed below the surface of the substrate 160. This is one non-limiting example of the surface to be contacted having topography. Each of the MEMS structures 150 in the non-limiting, illustrative, example of FIG. 6a comprises a respective electrically conductive contact surface 170. As shown in FIG. 6b, the microstructure inspection device 100 is pushed towards the substrate 160 until the probe tip surface 122 is put into electrical contact with the at least one, in this case two, electrically conductive contact surface 170, thereby enabling electrical inspection of the MEMS structure or structures 150. As further illustrated in FIG. 6b, when the elastically deformable and electrically conductive probe tip surface 122 is pushed against the surface of the substrate 160 as described herein, the probe tip surface 122 is caused to deform elastically to protrude into any opening in the surface of the substrate 160, thereby enabling electrical contact with the MEMS structures 150, i.e. with the respective recessed electrically conductive contact surfaces 170 shown in FIG. 6b, below the surface of the substrate 160. Such recessed electrically conductive contact surfaces 170 may be formed on a distance of tens of nanometers up to hundreds of micrometers below the surface of the substrate 160. Depending on the depth to be reached and the size of the lateral opening, a suitable probe tip surface material should be selected. Alternatively, or additionally, to recessed electrically conductive surfaces the MEMS structure 150 may comprise electrically conductive surfaces on elements protruding from the surface of the substrate 160. A non-limiting example of such protrusions is micro needles, wherein electrically conductive surfaces may be located on the tapered side walls of the micro needles. A hard probe tip would in this example not be able to reach the electrically conductive surfaces for electrical testing since they would not reach beyond the tip of each needle. Pushing harder with a hard probe tip would cause the micro needles to break. The electrically conductive probe tip surface 122 of the present invention would however elastically deform around the micro needles and reach the contact surfaces. In this example, electrically conductive contact surfaces may instead be formed on a distance of tens of nanometers up to hundreds of micrometers above the surface of the substrate 160, on the protruding elements. Examples of groups of probe tip surface material having suitable properties for different applications are provided herein. For a recessed contact surface, materials in the ranges of 25-40 on the Shore A hardness scale or 0-50 on the Shore 00 hardness scale are preferably selected, so that they will be soft enough, or elastically deformable enough, to reach the recessed contact surfaces.

Since the MEMS structures 150 may not have a planar surface part like conventional contact pads that are to be contacted, it is more challenging to both achieve the electrical contact and, especially, to do so in a manner that does not damage the delicate MEMS structure and/or scratches the surface of the substrate 160 and/or MEMS structure 150. In all of the above cases, the present invention solves all the problems of achieving electrical contact even when the contact surfaces are not planar and easy to reach, scratching or leaving imprints on the surface of the substrate 160 and the MEMS structure 150 and eliminates or at least greatly reduces the risk of damaging parts of the delicate MEMS structure, through having a soft/elastically deformable and electrically conductive probe tip surface 122.

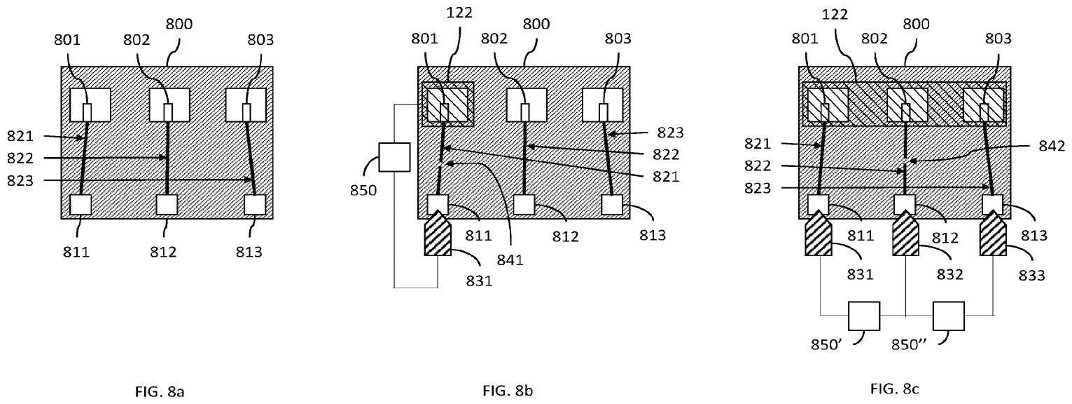

Conventional probe devices have hard probe tip surfaces that are not elastically deformable. Such conventional probe tip surfaces may comprise a variety of materials, lengths, shapes and probe tip radii. Wafer probing devices, sometimes referred to as probing needles, are typically made of tungsten pins with a fine end having an angular taper. Tungsten is a reliable conductor and has a high degree of hardness, needed to scratch the surface of a wafer and thereby ensuring good electrical contact during inspection. Of course, other materials of similar properties are also used in conventional probing devices. Typical probe tip surface radii range from sub-micron to several hundreds of microns depending on the application. Two examples of conventional electrical inspection devices 90, 90′ with a respective hard, not elastically deformable, probe tip 91, 91′ which are put into contact with a respective electrically conductive contact surface 170 of a substrate 160 are illustrated in FIG. 9. As can be seen from FIG. 9, the first conventional electrical inspection device 90 has a probe tip 91 with a very small probe tip radius, while the second conventional electrical inspection device 90′ has a probe tip 91′ with a larger probe tip radius compared to that of the first conventional electrical inspection device 90. In both cases however, the actual surface area of the substrate 160, and the actual surface area of the respective electrically conductive contact surface 170, which the respective conventional probe tip 91, 91′ is in contact with is significantly smaller compared to the possible contact area that can be achieved using embodiments of the electrical inspection device 100 or system 200 described herein, having an elastically deformable and electrically conductive probe tip surface 122. Using a conventional electrical inspection device it is therefore not possible to use one probe needle, one probe device or one probe tip to contact multiple electrical contact surfaces, e.g. contact pads, simultaneously. Instead, as shown in the example of FIG. 9, one probe device per electrical contact surface/contact pad is used. Probe cards are therefore typically comprised of multiple probe needles arranged in a pattern that matches the electrical contact surfaces/contact pads on the device under test (DUT). Using the inventive electrical inspection device 100 or system 200 however, the surface area of the elastically deformable and electrically conductive probe tip surface 122 can be made large enough to reach and electrically contact multiple electrical contact surfaces 170 at the same time, as illustrated in the non-limiting examples of FIGS. 5b, 6b and 8c. As a consequence, the multiple contacted electrical contact surfaces 170 will be short circuited. This use case scenario is further described in connection with FIG. 8c.

Of course, it is also possible to use a single elastically deformable and electrically conductive probe tip surface 122 of an electrical inspection device 100 or system 200 according to any embodiment described herein to contact and electrically inspect a single contact pad/electrical contact surface 170 on the device under test (DUT). A non-limiting example of this is illustrated in FIG. 6c, which shows that if there are multiple contact pads/electrical contact surfaces 170 on a DUT and only one is to be contacted (or if only a respective one is to be contacted by each electrical inspection device 100 if multiple electrical inspection devices 100 are arranged together as part of an electrical inspection system 200), the surface area (material footprint) of the probe tip surface 122 needs to be smaller that the pitch, or distance from center to center, of adjacent electrical contact surfaces 170 on the DUT. If the distance or pitch between the individual electrically inspected features (e.g. contact pads or MEMS structures) is smaller than the area of the probe tip surface and this causes simultaneous contact with two or more such features, short-circuiting occurs. The advantages of not risking damaging parts of the delicate MEMS structure 150 and further not leaving an imprint on or scratch the contacted surface is of course obtained in all embodiments, regardless of whether only one or multiple electrical contact surfaces 170 is/are contacted by one of the inventive probe tip surfaces 122. During inspection using the microstructure inspection device 100 or microstructure inspection system 200 according to any embodiment herein, the substrate 160 will typically first be moved in relation to the microstructure inspection device 100, in the x,y plane, to position the substrate 160, MEMS structure 150 and microstructure inspection device 100 correctly for inspection, and the push unit 110 will then push the probe tip unit 120 in the z direction to close the distance between the substrate 160 and the microstructure inspection device 100, specifically to put the probe tip surface 122 and the MEMS structure into physical contact, thereby enabling the electrical inspection.

Pushing the probe tip unit 120 in a first direction towards the substrate 160 means pushing the probe tip unit 120 towards the substrate 160 along the z-axis of the coordinate system (x, y, z) illustrated in FIGS. 1, 2, 7a and 7b. The z-axis is parallel to the longitudinal direction of the push unit 110 and the longitudinal direction of the microstructure inspection device 100 as a whole. The abutment force is herein defined as the force component directed towards the surface part to be inspected (part of the surface of the substrate or a surface part of the MEMS structure 150, as described above), in a direction parallel to the normal of the surface part to be inspected. In FIGS. 1, 2, 7a and 7b the normal of the surface part to be inspected is illustrated by an axis A. If the surface part to be inspected is planar and parallel to the x,y plane, as is the case in the example in FIGS. 1 and 2, the abutment force is equal to the force with which the probe tip unit 120 is pushed towards the substrate 160, and hence towards the surface part of the substrate or MEMS structure part to be inspected. In FIG. 1, the abutment force resulting from the push unit 110 pushing the probe tip unit 120 directed towards the substrate 160 is illustrated by the arrow F between the probe tip surface 122 and the MEMS structure 150.

As illustrated in FIGS. 7a and 7b, the surface part of the substrate or MEMS structure to be inspected may not be parallel to the x,y plane but instead be at an angle, tilted, in relation to the x,y plane. To solve this problem, in some embodiments the probe tip unit 120 may further be tiltably arranged in relation to the push unit 110. FIGS. 7a and 7b schematically illustrate such an embodiment of a microstructure inspection device 100, or system 200 comprising such a device 100, wherein the probe tip unit 120 is tiltably arranged in relation to the push unit 110. In the example of FIGS. 7a and 7b, the force component directed along the axis A and parallel to the normal of the surface part to be inspected, i.e. the abutment force, is denoted F′. In other words, in this embodiment the probe tip unit 120 advantageously involves a self-leveling tilt-correction mechanism that eliminates potential angular mismatch between the probing assembly and the device under test. Suitably, by configuring or arranging the probe tip unit 120 such that it is tiltable in relation to the push unit 110, the probe tip unit 120 will during inspection of a MEMS structure 150 tilt to accommodate to the surface of the substrate 160 and/or the surface of the MEMS structure 150 towards which it is pushed. Thereby, the area of the probe tip surface 122 that is put into contact with the part of the surface of the substrate 160 or MEMS structure 150 to be inspected, the DUT, will be maximized or at least greatly increased. This in turn maximizes or at least greatly increases the electrical contact between the probe tip surface 122 and the inspected DUT, which leads to a more reliable electrical inspection. At the same time the tilting to accommodate to the surface of the DUT contributes to protecting sensitive and fragile features of the DUT. In the case of a rotational push unit 110, such as for example a fine-thread screw, another advantageous effect of the self-leveling tilt-correction mechanism of the tiltably arranged probe tip unit 120 is that is contributes to stopping rotation of the probe tip 122 upon contact between the probe tip 122 and the DUT, thereby eliminating the application of torsional forces on the DUT by the probe tip 122.

As is apparent to a person skilled in the art, the probe tip unit 120 being tiltably arranged in relation to the push unit 110 can be achieved in many different manners known in the art.

The push unit 110 may be configured to push the probe tip unit 120 in the first direction with the abutment force F, F′ in response to a control signal C from a probe controller communicatively connected to the microstructure inspection device 100, for example the probe controller 210 shown in FIG. 2. Thereby, the application of force, or pressure, may suitably be automatically controlled, making the inspection of the electrical characteristic of at least one MEMS structure 150 according to embodiments of the present invention even more robust and reliable. The probe controller is in these embodiments configured to generate a control signal C, which is configured to control the push unit 110 of the microstructure inspection device 100 to push the probe tip unit in the first direction with the abutment force F, F′.

As is readily understood by a person skilled in the art, the abutment force may instead be expressed in the terms of a pressure, wherein the corresponding pressure is derived as the abutment force acting upon a defined surface area, in this case the area of the probe tip surface 122, upon which the force acts when the probe tip surface 122 is pushed against the substrate 160 or MEMS structure 150 and/or when the substrate 160 is pushed against the probe tip surface 122, according to any of the embodiments described herein. Hereinafter, the predetermined deformation threshold value may therefore interchangeably be referred to as the value of a force (N) or a pressure applied on a defined area (Pa, or N/m²).

The surface area of the electrically conductive and elastically deformable probe tip surface 122 may be selected to be in the interval of 0.01 mm² to 1 cm². In many applications a probe tip surface area may be in the interval 1 mm² to 1 cm². Areas within these ranges, including the end points, are suitable for inspecting an electrical characteristic a MEMS structure. In some non-limiting embodiments, the surface area of the probe tip surface 122 is at least 20 mm² and at most 30 mm². In one non-limiting embodiment, the surface area of the probe tip surface 122 is 25 mm², or close to 25 mm², i.e. within manufacturing tolerances.

The given abutment force applied by the push unit(s) 110 and the probe tip surface area result in the applied pressure that can be calculated by the well-known relation: F=p*A, where F is the abutment force, p is the pressure, and A is the area of the probe tip surface.

As a non-limiting examples of an abutment force, if the pressure applied is 0.0001 MPa=100 Pa (the lower end point of the example interval given herein) and the probe tip surface area is 0.01 mm²=0.00000001 m² (the lower end point of the example interval given herein), the corresponding force applied is:

100 Pa×0.00000001 m²=0.000001 N

As a further non-limiting examples of an abutment force, if the pressure applied is 3 MPa=3 000 000 Pa (the upper end point of the example interval given herein) and the probe tip surface area is 1 cm²=0.0001 m² (the upper end point of the example interval given herein), the corresponding force applied is:

3 000 000 Pa×0.0001 m²=300 N

The thickness of the probe tip surface 122 may differ depending on the application and material(s) selected, but a suitable range may be 0.05-5 mm. In one non-limiting embodiment, the thickness of the probe tip surface 122 may be selected to 0.5 mm, or close to 0.5 mm, within manufacturing tolerances. However, the functioning of the invention is not dependent on the above given thickness examples, but other suitable thicknesses may be used for different applications, as is readily apparent to a person skilled in the art.

As shown in FIG. 1, the probe tip unit 120 may comprise a probe tip body 121 attached to the probe tip surface 122. Alternatively, the probe tip unit 120 may be in one part, comprising only the probe tip surface 122 which is then directly attached to the push unit 110. In any of these embodiments, the surface area of the distal end surface of the probe tip body 121, or the distal end surface of the push unit 110 if there is no separate probe tip body, that is attached to the proximal end surface of the probe tip surface 122, is equal to or larger than the surface area of the proximal end surface of the probe tip surface 122. All parts of the microstructure inspection device 100 are symmetrical around the z-axis, meaning that according to these embodiments no part of the probe tip surface 122 extends beyond the surface area of the part directly exerting a force or pressure upon it. Thereby, an even distribution of force and pressure upon contact with the surface of the substrate 160 and/or MEMS structure 150 to be inspected is ensured. Of course, if the surface part of the MEMS structure that is to be inspected is not planar, but instead comprises topography, the pressure distribution will be affected by the topography. This further ensures that the probe tip surface 122 does not to a large degree deform elastically outside of the intended contact area, i.e. spill outside of the probe tip unit in the x,y plane, which would risk reducing the electrical contact achieved in the intended contact area or reduce the softening effect that protects the surfaces and delicate MEMS structures. Of course, if the probe tip unit 120 comprises a probe tip body 121, the distal end surface area of the push unit 110 does not have to be equal to or larger than the proximal surface end of the probe tip surface 122.

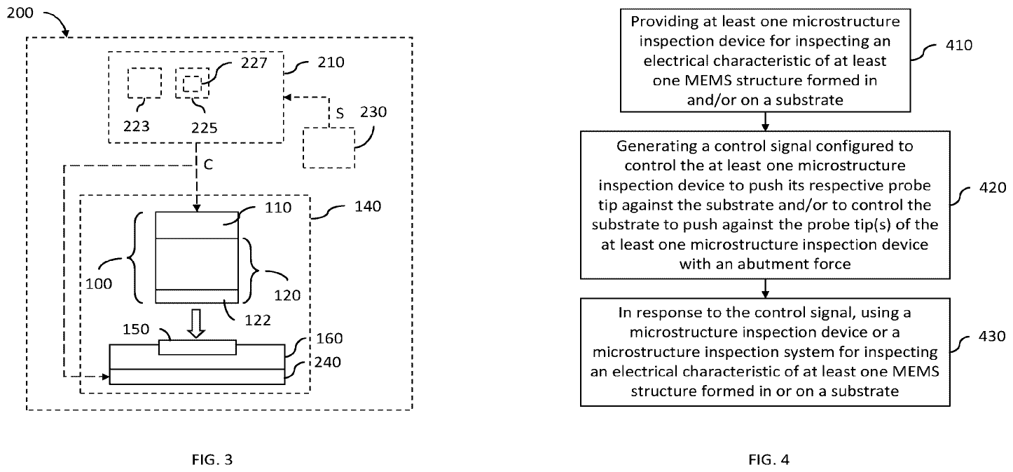

FIG. 2 schematically discloses a microstructure inspection device 100 according to any embodiment described in connection with FIG. 1, when the microstructure inspection device 100 has been pushed towards the substrate 160 and is in abutment with the DUT, in this case a MEMS structure 150. In other words, FIG. 2 shows the microstructure inspection device 100 when electrical contact between the probe tip surface 122 and the surface of the DUT has been achieved. FIG. 2 shows the same elements as FIG. 1, although they may not all be identical in shape and size to show that the figures are only schematic representations. The microstructure inspection device 100 in FIG. 2 further comprises an optional element in the form of a probe fixation device 140), being arranged to hold the at least one microstructure inspection device 100. The probe fixation device is described further in connection with FIG. 3.

A second aspect of the invention will now be described with reference to FIG. 3.

Turning to FIG. 3, there is shown a microstructure inspection system 200 for inspecting an electrical characteristic of at least one micro electromechanical system, MEMS, structure 150 formed in or on a substrate 160. The microstructure inspection system 200 comprises at least one microstructure inspection device 100. The microstructure inspection system 200 further comprises a substrate 160 having at least one micro electromechanical system, MEMS, structure 150 formed thereon or therein.

In all embodiments of the system 200, each of the at least one microstructure inspection device 100 comprise a probe tip unit 120 having an electrically conductive and elastically deformable probe tip surface 122 configured to deform elastically when subjected to a force greater than a predetermined deformation threshold value. In some embodiments of the microstructure inspection system 200, the at least one microstructure inspection device 100 also comprises the push unit 110 that is configured to push the probe tip unit 120 towards the substrate 160. In other embodiments the microstructure inspection system 200 instead, or additionally, comprises a substrate push unit 240 that is configured to push the substrate 160 towards the probe tip unit 120. In some embodiments comprising both the at least one push unit 110 and the substrate push unit 240, they may be configured to push the probe tip unit 120 and the substrate push unit 240 towards or against each other. For any of these embodiments of how the probe tip unit 120 and the substrate 160 are pushed towards or against each other, each of the at least one microstructure inspection device 100 may further be according to any one of the embodiments described herein.

Pushing the substrate 160 towards or against the probe tip unit 120 means pushing the substrate 160 in a direction opposite to the first direction. In embodiments comprising only a substrate push unit 240 and no push unit 110, the abutment force is defined as the force component directed towards the probe tip unit 120, parallel to the normal of the surface part to be inspected. In embodiments comprising both at least one push unit 110 and the substrate push unit 240, the abutment force is defined the combination of the force component directed towards the probe tip unit 120 by the substrate push unit 240, and the force component directed towards the substrate 160 by the at least one push unit 110, both force components being parallel to the normal of the surface part to be inspected.

The microstructure inspection system 200 further comprises a probe fixation device 140 arranged to hold the at least one microstructure inspection device 100. The probe fixation device is suitably configured to operatively connect the microstructure inspection device 100 to the other elements of the probing set-up, including actuators for providing movements in the x, y-plane, thereby enabling transfer of the microstructure inspection device 100 in the x,y plane and alignment with a MEMS structure 150 to be inspected. The probe fixation device 140 may further be arranged to hold the substrate 160. If the system 200 comprises a substrate push unit 240, the probe fixation device 140 may also be arranged to hold the substrate push unit 240.

The hardness of the at least one micro electromechanical system, MEMS, structure 150 to be inspected is higher than the hardness the electrically conductive and elastically deformable probe tip surface 122 of the probe unit 120 of each of the at least one microstructure inspection device 100.

Since the hardness of the at least one MEMS structure 150, or DUT, to be inspected is higher than the hardness the electrically conductive and elastically deformable probe tip surface 122 of the probe unit 120 of each of the at least one microstructure inspection device 100, the electrically conductive and elastically deformable probe tip surface 122 will deform elastically when abutted against the surface of the at least one MEMS structure 150 formed in or on the substrate 160. Thereby, the microstructure inspection device 100 can be put into electrical contact with the MEMS structure 150, or MEMS device under test (DUT), without risking damaging parts of the delicate MEMS structure 150 and further without leaving an imprint on or scratch the surface of the MEMS structure 150 or substrate 160, if one or more of the at least one MEMS structure 150 is formed within the substrate 160.

The hardness of the electrically conductive and elastically deformable probe tip surface 122 may be below or equal to 60 Durometer on the Shore A hardness scale. The hardness of the electrically conductive and elastically deformable probe tip surface 122 may further be below or equal to 50 Durometer on the Shore 00 hardness scale, be in the interval 40-60 Durometer on the Shore A hardness scale, including the end points, or be in the interval 25-40 Durometer on the Shore A hardness scale, including the end points. As is known to a person skilled in the art, a hardness value below 60 Durometer on the Shore A hardness scale would include all Shore Durometer values on the Shore 00 hardness scale, including Shore Durometer, or simply Durometer, values in the range 0-50 on the Shore 00 hardness scale, as the materials measured using the Shore 00 hardness scale are softer than those measured using the Shore A hardness scale.

In some embodiments, it is possible to simultaneously contact a plurality of contact areas, or MEMS structures 150, at the same time. To achieve this, the at least one microstructure inspection device 100 of the microstructure inspection system 200 may comprise a plurality of microstructure inspection devices 100. The probe fixation unit 140 is in these embodiments configured to hold each of the plurality of microstructure inspection devices 100. The probe fixation unit 140 may for this purpose be provided on, be operatively connected to, or form part of a probe card. Alternatively, or additionally, to using a plurality of microstructure inspection devices 100, each of the at least one microstructure inspection device 100 of the microstructure inspection system 200 may be configured to contact more than one contact areas, or MEMS structures 150, at the same time. This is achieved by the size and shape of the probe tip surface 122 being selected such that it can reach and enable electrical contact with more than one contact area, or MEMS structures150, at the same time, for a certain application.

The microstructure inspection system 200 may further comprise a probe controller 210 configured to generate a control signal C. The control signal C may be configured to control each push unit 110 of at least one microstructure inspection device 100, independently or simultaneously, to push the probe tip unit 120 in a respective first direction towards the substrate 160 with the abutment force described in connection with the microstructure inspection device 100. Alternatively, the control signal C may be configured to control the substrate push unit 240 to push the substrate 160 towards the at least one probe tip unit 120 with said abutment force. Alternatively, the control signal C may be configured to both control each push unit 110 of the at least one microstructure inspection device 100, independently or simultaneously, to push its respective probe tip unit 120 in the first direction towards the substrate with a first force and to control the substrate push unit 240 to push the substrate 160 towards the at least one probe tip unit 120 with a second force, wherein the combination of the first force and the second force is equal to said abutment force.

In some embodiments, the microstructure inspection system 200 may further comprise an input device 230, configured to receive input in the form of an input abutment force value from a user interacting with the input device 230 via a user interface, to generate an input signal S indicative of the input abutment force value received via the user interface and to send the input signal S to the controller 120. In these embodiments, the controller 120 is in turn configured to receive the input signal S from the input device 230, interpret the signal S to derive the abutment force value, and to generate the control signal C such that the abutment force is set to the input abutment force value. Thereby, a user of the system is enabled to manually control the abutment force via the input device and the thereto connected user interface. This may e.g. be desirable if the user notices during use of the microstructure inspection system 200 that an adjustment of the applied abutment force is needed in order to ensure proper inspection results considering the properties of one or more components of microstructure inspection system 200 and properties of the MEMS structure/DUT.

As further illustrated in FIG. 3, it is generally advantageous if the probe controller 210 is configured to effect the above-described procedure in an automatic manner by executing a computer program 227. Therefore, the probe controller 210 may include a memory unit 225, i.e. non-volatile data carrier, storing the computer program 227, which, in turn, contains software for making processing circuitry in the form of at least one processor 223 in the probe controller 210 execute the actions mentioned in this disclosure when the computer program 227 is run on the at least one processor 223.

The process steps performed by the probe controller 210 may be controlled by means of a programmed processor. Moreover, although the embodiments described above with reference to the drawings comprise a processor and processes performed in at least one processor, the invention thus also extends to computer programs, particularly computer programs on or in a carrier, adapted for putting relevant process steps of the invention into practice. The program may be in the form of source code, object code, a code intermediate source and object code such as in partially compiled form, or in any other form suitable for use in the implementation of the process according to the invention. The program may either be a part of an operating system or be a separate application. The carrier may be any entity or device capable of carrying the program. For example, the carrier may comprise a storage medium, such as a Flash memory, a ROM (Read Only Memory), for example a DVD (Digital Video/Versatile Disk), a CD (Compact Disc) or a semiconductor ROM, an EPROM (Erasable Programmable Read-Only Memory), an EEPROM (Electrically Erasable Programmable Read-Only Memory), or a magnetic recording medium, for example a floppy disc or hard disc. Further, the carrier may be a transmissible carrier such as an electrical or optical signal which may be conveyed via electrical or optical cable or by radio or by other means. When the program is embodied in a signal, which may be conveyed, directly by a cable or other device or means, the carrier may be consti-tuted by such cable or device or means. Alternatively, the carrier may be an integrated circuit in which the program is embedded, the integrated circuit being adapted for performing, or for use in the performance of, the relevant processes.

In a third aspect, the invention includes use of a microstructure inspection device 100 according to any of the embodiments described in connection with FIGS. 1, 2, 5a, 5b, 6a, 6b, 7a and 7b, or a microstructure inspection system 200 according to any of the embodiments described in connection with FIG. 3, for inspecting an electrical characteristic of at least one micro electromechanical system, MEMS, structure 150 formed in or on a substrate 160.

With reference to the flow diagram in FIG. 4, we will now describe a method of using a microstructure inspection device 100 or a microstructure inspection system 200, according to any of the embodiments described herein, for inspecting an electrical characteristic of at least one micro electromechanical system, MEMS, structure 150 formed in or on a substrate 160. The method illustrated in FIG. 4 comprises:

In step 410: Providing at least one microstructure inspection device 100 or a microstructure inspection system 200 for inspecting an electrical characteristic of at least one MEMS structure 150 formed in and/or on a substrate 160.

In step 420: Generating, by the controller 210, a control signal C.

The control signal C may be configured to control the push unit 110 of at least one microstructure inspection device 100 to push its respective probe tip unit 120 in a respective first direction towards or against the substrate 160 with an abutment force. Alternatively, the control signal C is configured to control the substrate push unit 240 to push the substrate 160 towards or against the at least one microstructure inspection device 100 with said abutment force. Alternatively, the control signal C is configured to control each push unit 110 of the at least one microstructure inspection device 100, independently or simultaneously, to push its respective probe tip unit 120 in the first direction and to also control the substrate push unit 240 to push the substrate 160 towards the at least one probe tip unit 120, i.e. in a direction opposite to the first direction, with a combined force that is equal to said abutment force.

As described herein, the abutment force is greater than the predetermined deformation threshold value for the elastically deformable probe tip surface 122.

As further described herein, the force applied may interchangeably be defined as an applied pressure, using knowledge of the area of the probe tip surface 122. According to the alternative embodiments herein, the probe tip surface 122, as it is part of the probe tip unit 120, will be subjected to pressure either when it is being pushed in the first direction against the surface of the MEMS structure 150 or the surface of the substrate 160, in the case the MEMS structure is formed therein, and/or when the substrate 160 is being pushed against the probe tip unit 120.

Generating the control signal C in step 420 may in some embodiments comprise receiving, from an input device 230 communicatively connected to the controller 120, an input signal indicative of an input abutment force value and generating the control signal C such that the abutment force is set to the input abutment force value.

In step 430: In response to the control signal C, using a microstructure inspection device 100 or a microstructure inspection system 200 for inspecting an electrical characteristic of at least one MEMS structure 150 formed in or on a substrate 160.

In some embodiments, this includes controlling the push unit 110 of at least one microstructure inspection device 100, of the microstructure inspection device 100 or microstructure inspection system 200, to push its respective probe tip unit 120 in the first direction with the abutment force. In other embodiments, this includes controlling the substrate push unit 240 of a microstructure inspection system 200 to push the substrate 160 towards the at least one probe tip unit 120, in a direction opposite to the first direction, with the abutment force. In yet other embodiments, this includes controlling the push unit 110 of at least one microstructure inspection device 100 of the microstructure inspection system 200 to push its respective probe tip unit 120 in the first direction with a first force and controlling the substrate push unit 240 of a microstructure inspection system 200 to push the substrate 160 towards the at least one probe tip unit 120, i.e. in a direction opposite to the first direction, with a second force, such that the combination of the first force and the second force is the abutment force.

In all embodiments herein, the electrically conductive and elastically deformable probe tip surface 122 is suitably made from an electrically conductive and elastically deformable material. The electrically conductive and elastically deformable material may for example be an electrically conductive material based on, or comprising, a jelly-like or gel-like elastomer, a soft elastomer such as e.g. silicone, or a medium soft elastomer, e.g. a nitrile, neoprene, ethylene propylene, etc., as exemplified herein. Of course, the probe tip surface may be made from a single material or a combination of materials. The probe tip surface may comprise any of the materials exemplified herein and/or any other suitable material(s) that is/are similar in softness to the exemplified materials, electrically conductive and elastically deformable.

When we refer to a material herein as being soft, we refer to the definitions of extra soft, soft and medium soft according to the Shore A hardness scale, wherein an extra soft material (including jelly-like or gel-like materials) is approximately within the range 0-50 on the Shore 00 hardness scale, a soft material is approximately within the range 25-40 on the Shore A hardness scale, and a medium-soft material is approximately within the range 40-60 on the Shore A hardness scale.

In table 1 below, some non-limiting examples of soft materials suitable as probe tip surface materials for any embodiment herein are shown together with their approximate softness/hardness defined according to the Shore 00 or Shore A hardness scales.

TABLE 1

| | Shore | Shore | Typical Probe Tip | |
|---|---|---|---|---|
| Material | Durometer | scale | Pressure Range | |
| Jelly- and gel-like elastomers | 0-50 | 00 | 0.0001-0.15 | Mpa |
| Soft elastomers, e.g. silicone | 25-40 | A | 0.015-1.5 | MPa |
| Medium-soft elastomers, e.g. | 40-60 | A | 0.03-3 | MPa |
| nitriles, neoprene, ethylene | | | | |
| propylene, etc. | | | | |

For any of the alternative surface areas of the electrically conductive and elastically deformable probe tip surface material examples given herein, the predetermined deformation threshold value may be set to a force that generates a pressure on the probe tip surface that is equal to or more than 0.0001 MPa and equal to or less than 3 MPa when the microstructure inspection device 100, or specifically the probe tip surface 122, and the MEMS structure 150 and/or the substrate 160 comprising the MEMS structure 150 are pressed against each other. Suitably, an electrically conductive and elastically deformable probe tip surface made of a material (or a combination of materials) that is configured to deform elastically when subjected to a pressure within the interval of 0.0001 MPa to 3 MPa for the given areas is a material that is significantly softer than any material used in the substrate, or MEMS structure formed in or on the substrate, against which it is to be pressed during inspection. Therefore, the electrically conductive and elastically deformable probe tip surface will advantageously deform elastically when pressed against the substrate, or MEMS structure formed in or on the substrate, during inspection without risking damaging parts of the delicate MEMS structure and further without leaving an imprint on or scratch the surface of the MEMS structure. Using the definitions of the Shore hardness scale, materials that deform elastically when subjected to pressure within the interval of 0.0001 MPa to 3 MPa for the given surface areas are defined as either extra soft, soft, or medium soft materials, as exemplified in Table 1 above. Of course, any other suitable material or material combination fulfilling the criteria of being electrically conductive and deforming elastically when exposed to pressures within any of the above exemplified intervals may also be applied. Advantageously, for any material fulfilling these criteria, including the examples given herein, the aim that the inspection device can be put into electrical contact with the MEMS structure, or MEMS device under test (DUT), without risking damaging parts of the delicate MEMS structure and further without leaving an imprint on or scratch the surface of the MEMS structure or substrate, is achieved. In some applications, it may be feasible to use for example a suitable electrolyte as the material for the probe tip surface 122.

In some embodiments, the predetermined deformation threshold value may be set to a force that generates a pressure on the probe tip surface that is equal to or more than 0.0001 MPa and equal to or less than 0.15 MPa. Materials that will deform elastically when exposed to pressures within this interval have a shore Durometer value of 0-50 on the Shore 00 hardness scale and are defined as extra soft materials according to the Shore hardness scale. In other embodiments, the predetermined deformation threshold value may be set to a force that generates a pressure on the probe tip surface that is equal to or more than 0.15 MPa and equal to or less than 1.5 MPa. Materials that will deform elastically when exposed to pressures within this interval have a shore Durometer value of 25-40 on the Shore A hardness scale and are defined as soft materials according to the Shore hardness scale. In yet other embodiments, the predetermined deformation threshold value may be set to a force that generates a pressure on the probe tip surface that is equal to or more than 0.03 MPa and equal to or less than 3 MPa. Materials that will deform elastically when exposed to pressures within this interval have a shore Durometer value of 40-60 on the Shore A hardness scale and are defined as medium soft materials according to the Shore hardness scale.

In the figures the probe tip surface 122 is shown as being flat on the side facing the substrate 160, i.e. having a flat, or planar, end. However, the probe tip surface 122 may have any suitable shape and topography for the application in which it is used. Furthermore, when the probe tip surface is pushed against the substrate, and/or the substrate is pushed against the probe tip surface, with the abutment force, the elastically deformable probe tip surface 122 will deform to accommodate to the topography that it is pressed against, for example in the manner illustrated in FIG. 6b. In some embodiments, the probe tip surface 122 may comprise topography in the form of micro patterns, made during production of the probe tip surface or at any other time before the microstructure inspection device 100 is used for electrical inspection. Micropatterning suitably allows the probe tip surface 122 to even better accommodate to irregularities or topography of the MEMS structure surface to be contacted. In some embodiment wherein the probe tip surface 122 comprises micropatterning, the micropatterning may advantageously be application-specific patterning, i.e. having arrays/patterns/shapes of the like of conductive polymer features that match features on the MEMS structure surface to be contacted. This may for example be advantageous if one or more contact area or contact surface (e.g. a metallization) on the MEMS structure 150 to be inspected is hard to reach, e.g. being located lower than the surface of the substrate 160 as illustrated in FIG. 6b, located in or on a side wall of a MEMS structure 150, or even being partially hidden from view under part of the MEMS structure 150. In all these examples, the elastically deformable probe tip surface 122 enables electrical inspection where it would be impossible to achieve or the risk of damaging the MEMS structure in doing so would be imminent if prior probing technology was used.

When we refer to the material(s) of the substrate and components thereof, therein or thereon, such as any three-dimensional MEMS structure or other device under test (DUT), the materials are significantly harder than that/those of the probe tip surface 122. Therefore other hardness tests and units apply when the hardness of the material(s) of the substrate or any components thereof, therein or thereon, such as any three-dimensional MEMS structure or other device under test (DUT). In table 2 below, some non-limiting examples of hard materials suitable to be used in the substrate, wafer, or components thereof, therein or thereon are shown together with their approximate hardness defined according to the Brinell Hardness [MPa], Vickers Hardness [HV] or Shore D hardness scale.

TABLE 2

| | Brinell Hardness | Vickers Hardness | |
|---|---|---|---|
| Material | [MPa] | [HV] | Shore D |
| Si | 2300 | | |
| SiO2 | | 1103-1260 | |
| Si3N4 | | 1700-2200 | |
| Au | 188-245 | | |
| Al | 160-550 | | |
| Cu | 235-878 | | |
| Ti | 716-2770 | | |
| Cured photoresist | | | >10 |

In the present context, we may refer to the materials in table 2 and any materials with corresponding hardness as hard materials. By this we mean that they are hard, in fact significantly harder, in comparison to the material(s) of the elastically deformable probe tip surface 122. In other words, any material listed in table 1, i.e. a soft material, that is pushed or pressed against any material listed in table 2, i.e. a hard material, will deform elastically when a sufficiently high force or pressure is applied. Materials listed in table 2, the hard materials, on the other hand will not deform by any means during this process.

In any embodiment herein, the probe tip surface 122 may be removable and replaceable, so that the probe tip surface 122 can be replaced when needed, e.g. after a certain number of probing/electrical inspection cycles or when assessment of the probe tip surface material indicates that the properties of the material are no longer satisfactory. Reasons for the material deteriorating includes mechanical wear and/or picking up particles, etc.

A common challenge in electrical testing of complex MEMS devices is that certain tests cannot be realized by e.g. probing of test structures or of the electrical contacts of the device itself using conventional probes. These tests include but are not limited to leakage, crosstalk and/or parasitic characteristics of the device. This problem and how it is solved by embodiments disclosed herein will now be explained in connection with FIGS. 8a, 8b and 8c.

FIG. 8a schematically discloses functional MEMS structures in and/or on a substrate, while FIGS. 8b and 8c schematically disclose electrical inspection of the functional MEMS structures of FIG. 8a using one or more embodiment of the invention.

Turning first to FIG. 8a, there is schematically shown a substrate 800, for example being a substrate or die. As shown in FIG. 8a, the substrate 800 comprises a number of functional MEMS structures, in this example a first MEMS structure 801, a second MEMS structure 802 and a third MEMS structure 803. The substrate 800 further comprises a first contact or bond pad 811 (hereinafter referred to as contact pad), a second contact pad 812 and a third contact pad 813 configured to be contacted by an electrical inspection device 100, and corresponding first, second and third metal traces 821, 822, 823 that lead electrical signals or currents from each of first, second and third contact or bond pad 811, 812, 813 to the respective first, second and third MEMS structure 801, 802, 803. For electrical inspection of the MEMS structures 801, 802, 803, the respective contact pads 811, 812, 813 are typically probed using conventional probes with hard probe tips, such as the exemplary conventional probe needles 831, 832 and 833 illustrated in FIGS. 8b and 8c. However, there is no way to verify if there is an electrical connection between for example the contact or bond pad 811 and the MEMS structure 801, or if a defect, for instance on a metal trace, causes an open circuit (float). Using conventional probing technology, the MEMS structures 801, 802, 803 can in many instances not be contacted directly by the conventional probes as the structures would be damaged or destroyed by the mechanical impact of conventional probe tips or needles, or due to the small area and/or fragile elements of the respective MEMS structure 801, 802, 803.

In general a contact pad for conventional probing or wire bonding must be on the order of at least 80×80 μm² to avoid the problems described above. Functional MEMS structures, such as the example MEMS structures 801, 802, 803 in FIGS. 8a to 8c can be considerably smaller, for example in the order of magnitude of a few μm². Using embodiments of the microstructure inspection device 100 or microstructure inspection system 200 presented herein, probing, and electrical inspection of such small MEMS structures is enabled. In FIGS. 8b and 8c, two examples of electrical inspection of the functional MEMS structures of FIG. 8a using one or more embodiment of the invention are schematically illustrated.

FIG. 8b shows the substrate 800 of FIG. 8a, with the difference that the first metal trace 821 is broken, i.e. has a defect 841, which causes an open circuit. It is not possible to detect an open circuit, caused by for example a broken metal trace, by conventional means of electrical probing. However, by electrically contacting the functional MEMS structures 801, 802, 803 with the microstructure inspection device 100 according to any embodiment herein, having the electrically conductive and elastically deformable probe tip surface 122, and measuring resistance between the probe tip unit 122 contacting the first MEMS structure 801 and the first contact pad 811 contacted for example using the first conventional probe needle 831, open circuits can be detected and other electrical characterization can be performed. Resistance may be measured using a first resistance measurement device 850 of any suitable kind, for example but not limited to a digital multimeter (DMM) and/or a source measure unit (SMU). This is possible due to the electrically conductive and elastically deformable probe tip surface 122 enabling contact with small and/or fragile MEMS structures, in manners described herein, that would not be possible to contact using conventional probing technology.

As shown in FIG. 8c, it is possible to contact multiple functional MEMS structures 801, 802, 803 at the same time, using one probe tip surface 122 configured to cover the area of the multiple MEMS structures 801, 802, 803. By doing so, i.e. using one probe tip surface 122 configured to cover the area of and electrically contact the multiple MEMS structures 801, 802, 803, the multiple MEMS structures 801, 802, 803 are short-circuited, and it is possible to measure and/or electrically characterize the MEMS structures 801, 802, 803 by conventional probing of at least two or the thereto connected contact pads 811, 821, 813 using the conventional probe needles 831, 832 and 833. Furthermore, by measuring resistance or other means of electrical characterization using a second resistance measurement device 850′ and/or a third resistance measurement device 850″ between different pairs of the first, second and third contact pads 811, 821, 813 (typically done by multiplexing), open circuits, for example caused by the defect 842 in the second metal trace 822 as shown in FIG. 8c, or other failure modes can be detected. The second resistance measurement device 850′ and/or the third resistance measurement device 850″ may be of any suitable kind, for example but not limited to a DMM and/or an SMU.

Variations to the disclosed embodiments can be understood and effected by those skilled in the art in practicing the claimed invention, from a study of the drawings, the disclosure, and the appended claims.

The term “comprises/comprising” when used in this specification is taken to specify the presence of stated features, integers, steps, or components. The term does not preclude the presence or addition of one or more additional elements, features, integers, steps or components or groups thereof. The indefinite article “a” or “an” does not exclude a plurality. In the claims, the word “or” is not to be interpreted as an exclusive or (sometimes referred to as “XOR”). On the contrary, expressions such as “A or B” covers all the cases “A and not B”, “B and not A” and “A and B”, unless otherwise indicated. The mere fact that certain measures are recited in mutually different dependent claims does not indicate that a combination of these measures cannot be used to advantage. Any reference signs in the claims should not be construed as limiting the scope.

It is also to be noted that features from the various embodiments described herein may freely be combined, unless it is explicitly stated that such a combination would be unsuitable.

The invention is not restricted to the described embodiments in the figures but may be varied freely within the scope of the claims.

1. A microstructure inspection device for inspecting an electrical characteristic of at least one micro electromechanical system (MEMS) structure formed in or on a substrate, the microstructure inspection device comprising:
a probe tip having an electrically conductive and elastically deformable probe tip surface configured to deform elastically when subjected to a force greater than a predetermined deformation threshold value; and
a pusher configured to push the probe tip in a first direction towards a substrate, the pusher being configured to push the probe tip in the first direction with an abutment force that is greater than the predetermined deformation threshold value.

2. The microstructure inspection device of claim 1, wherein the surface area of the electrically conductive and elastically deformable probe tip surface is at least 0.01 mm² and at most 1 cm².

3. The microstructure inspection device of claim 2, wherein the predetermined deformation threshold value is a force that generates a pressure on the probe tip surface that is equal to or more than 0.0001 MPa and equal to or less than 3 MPa.

4. The microstructure inspection device of claim 3, wherein the predetermined deformation threshold value is a force that generates a pressure on the probe tip surface that is equal to or more than 0.0001 MPa and equal to or less than 0.15 MPa.

5. The microstructure inspection device of claim 3, wherein the predetermined deformation threshold value is a force that generates a pressure on the probe tip surface that is equal to or more than 0.15 MPa and equal to or less than 1.5 MPa.

6. The microstructure inspection device of claim 3, wherein the predetermined deformation threshold value is a force that generates a pressure on the probe tip surface that is equal to or more than 0.3 MPa and equal to or less than 3 MPa.

7. The microstructure inspection device of claim 1, wherein the pusher unit is configured to push the probe tip in said first direction with said abutment force in response to a control signal from a probe controller.

8. The microstructure inspection device of claim 1, wherein the pusher is a linear actuator configured to push the probe tip in said first direction with the abutment force.

9. The microstructure inspection device of claim 8, wherein the pusher comprises one of a fine-thread screw, a piston, an electromagnetic actuator, and a piezoelectric actuator.

10. The microstructure inspection device of claim 1, wherein the probe tip is tiltably arranged in relation to the pusher.

11. A microstructure inspection system for inspecting an electrical characteristic of at least one micro electromechanical system (MEMS) structure formed in or on a substrate, the microstructure inspection system comprising:
at least one microstructure inspection device comprising
a probe tip having an electrically conductive and elastically deformable probe tip surface configured to deform elastically when subjected to a force greater than a predetermined deformation threshold value;
a probe fixation device, being arranged configured to hold the at least one microstructure inspection device; and,
a substrate having at least one micro electromechanical system (MEMS) structure formed thereon or therein,
wherein a hardness of the at least one micro electromechanical system (MEMS) structure to be inspected is higher than a hardness of the electrically conductive and elastically deformable probe tip surface of the probe tip of the respective at least one microstructure inspection device, and
wherein one of: the at least one microstructure inspection device comprises a pusher configured to push the probe tip in a first direction towards the substrate, and the microstructure inspection system comprises a substrate pusher configured to push the substrate towards and against the probe tip with an abutment force that is greater than the predetermined deformation threshold value.

12. The microstructure inspection system of claim 11, wherein the hardness of the electrically conductive and elastically deformable probe tip surface is below or equal to 60 Durometer on the Shore A hardness scale.

13. The microstructure inspection system of claim 12, wherein the hardness of the electrically conductive and elastically deformable probe tip surface is below or equal to 50 Durometer on the Shore 00 hardness scale.

14. The microstructure inspection system of claim 12, wherein the hardness of the electrically conductive and elastically deformable probe tip surface is in an interval 40-60 Durometer on the Shore A hardness scale, including end points thereof.

15. The microstructure inspection system of claim 12, wherein the hardness of the electrically conductive and elastically deformable probe tip surface is in an interval 25-40 Durometer on the Shore A hardness scale, including the end points t thereof.

16. The microstructure inspection system of claim 11, further comprising a probe controller configured to generate a control signal configured to one of:
(i) control the pusher of the respective at least one microstructure inspection device, independently or simultaneously, to push the probe tip in the first direction with said abutment force,
control the substrate pusher to push the substrate towards the respective probe tip with said abutment force, and
control the respective pusher of the at least one microstructure inspection device, independently or simultaneously, to push the respective probe tip in the first direction towards the substrate with a first force and to control the substrate pusher to push the substrate towards the respective probe tip with a second force, a combination of the first force and the second force being equal to said abutment force.

17. (canceled)

18. A method comprising:
providing the microstructure inspection device of claim 1; and
inspecting the electrical characteristic of the at least one micro electromechanical system (MEMS) structure formed in or on the substrate.

19. A method comprising:
providing the microstructure inspection system according to claim 11; and
inspecting the electrical characteristic of the at least one micro electromechanical system (MEMS) structure formed in or on the substrate.

20. The microstructure inspective device of claim 9, wherein the piston is a hydraulic piston.
